(19) United States
(12) Patent Application Publication
(10) Pub. No.: US 2010/0212594 A1
(43) Pub. Date: Aug. 26, 2010

(54) SUBSTRATE MOUNTING MECHANISM AND SUBSTRATE PROCESSING APPARATUS HAVING SAME

(75) Inventors: Masamichi HARA, Nirasaki-shi (JP); Atsushi GOMI, Nirasaki-shi (JP); Shinji MAEKAWA, Nirasaki-shi (JP); Satoshi TAGA, Nirasaki-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: TOKYO ELECTRON LIMITED, Tokyo (JP)

(21) Appl. No.: 12/721,954

(22) Filed: Mar. 11, 2010

Related U.S. Application Data
(63) Continuation of application No. PCT/JP08/65877, filed on Sep. 3, 2008.

(30) Foreign Application Priority Data
Sep. 11, 2007 (JP) 2007-235042

(51) Int. Cl. H01L 21/46

(52) U.S. Cl. 118/725; 118/58; 118/69; 257/E21.482

(57) ABSTRACT

A substrate mounting mechanism on which a substrate is placed is provided. The mechanism includes a heater plate having a substrate mounting surface, and a first insertion hole having large and small diameter portions, and a temperature control jacket formed to cover at least a surface of the heater plate other than the substrate mounting surface and having a non-deposition temperature a second insertion hole having large and small diameter portions. The mechanism further includes a first lift pin having a cover inserted into the large diameter portion of the first insertion hole and a shaft inserted into both the large and small diameter portions of the first insertion hole, and a second lift pin having a cover to be inserted into the large diameter portion of the second insertion hole and a shaft to be inserted into both the large and small diameter portions of the second insertion hole.

This application is a Continuation Application of PCT International Application No. PCT/JP2008/065877 filed on Sep. 3, 2008, which designated the United States.

### FIELD OF THE INVENTION

The present invention relates to a substrate mounting mechanism having a heater to heat a substrate such as a semiconductor wafer mounted thereon in a processing chamber of a substrate processing apparatus such as a film forming apparatus, and a substrate processing apparatus including the substrate mounting mechanism.

### BACKGROUND OF THE INVENTION

As one of manufacturing processes of semiconductor devices, there is a CVD film forming process that is performed on a semiconductor wafer serving as a target substrate. In this process, the semiconductor wafer serving as a target substrate is heated to a specific temperature generally by using a heater plate (stage heater) also serving as a substrate mounting table. A general heater plate is disclosed in Japanese Patent Application Publication No. H10-326788.

It is ideal that a film is deposited only on the semiconductor wafer in the CVD film forming process. However, actually, a film is deposited on the heater plate which heats the semiconductor wafer, as well. That is because the heater plate has a deposition temperature or more. The film deposited on the heater plate is influenced by the rise and fall of the temperature of the chamber or the heater and repeatedly thermally expanded and contracted. Accordingly, a thermal stress is accumulated in the deposited film. Ultimately, the film is peeled off to generate particles. The generation of particles in the chamber may cause deterioration in production yield of the semiconductor devices.

### SUMMARY OF THE INVENTION

It is an object of the present invention to provide a substrate mounting mechanism capable of suppressing film deposition, and a substrate processing apparatus including the substrate mounting mechanism.

In accordance with a first aspect of the present invention, there is provided a substrate mounting mechanism including: a heater plate which includes a substrate mounting surface on which a target substrate is placed, a heater embedded therein to heat the target substrate to a deposition temperature at which a film is deposited, and a first lift pin insertion hole having a large diameter portion at a side close to the substrate mounting surface and a small diameter portion with a diameter smaller than that of the large diameter portion at a side away from the substrate mounting surface; and a temperature control jacket which is formed to cover at least a surface of the heater plate other than the substrate mounting surface, is set to have a non-deposition temperature below the deposition temperature, and includes a second lift pin insertion hole having a large diameter portion at a side close to the substrate mounting surface and a small diameter portion with a diameter smaller than that of the large diameter portion at a side away from the substrate mounting surface.

The substrate mounting mechanism further includes a first lift pin which is inserted into the first lift pin insertion hole and includes a cover inserted into the large diameter portion of the first lift pin insertion hole and a shaft connected to the cover and inserted into both the large diameter portion and the small diameter portion of the first lift pin insertion hole; and a second lift pin which is inserted into the second lift pin insertion hole and includes a cover inserted into the large diameter portion of the second lift pin insertion hole and a shaft connected to the cover and inserted into both the large diameter portion and the small diameter portion of the second lift pin insertion hole.

In accordance with a second aspect of the present invention, there is provided a substrate processing apparatus including a chamber accommodating a substrate mounting mechanism; a film forming section for performing a film forming process on a target substrate; and a substrate mounting mechanism. In the substrate processing apparatus, the substrate mounting mechanism includes a heater plate which includes a substrate mounting surface on which the target substrate is placed, a heater embedded therein to heat the target substrate to a deposition temperature at which a film is deposited, and a first lift pin insertion hole having a large diameter portion at a side close to the substrate mounting surface and a small diameter portion with a diameter smaller than that of the large diameter portion at a side away from the substrate mounting surface; and a temperature control jacket which is formed to cover at least a surface of the heater plate other than the substrate mounting surface, is set to have a non-deposition temperature below the deposition temperature, and includes a second lift pin insertion hole having a large diameter portion at a side close to the substrate mounting surface and a small diameter portion with a diameter smaller than that of the large diameter portion at a side away from the substrate mounting surface.

The substrate mounting mechanism further includes a first lift pin which is inserted into the first lift pin insertion hole and includes a cover inserted into the large diameter portion of the first lift pin insertion hole and a shaft connected to the cover and inserted into both the large diameter portion and the small diameter portion of the first lift pin insertion hole; and a second lift pin which is inserted into the second lift pin insertion hole and includes a cover inserted into the large diameter portion of the second lift pin insertion hole and a shaft connected to the cover and inserted into both the large diameter portion and the small diameter portion of the second lift pin insertion hole.

### BRIEF DESCRIPTION OF THE DRAWINGS

FIG. 1 is a cross sectional view schematically showing an example of a substrate processing apparatus in accordance with a first embodiment of the present invention.

FIG. 2 illustrates a relationship between a temperature of a target substrate and a deposition rate.

FIG. 3A is a cross sectional view showing a comparative example.

FIG. 3B is a cross sectional view showing the comparative example.

FIG. 4A is a cross sectional view showing the embodiment.

FIG. 4B is a cross sectional view showing the embodiment.

FIG. 5A is a cross sectional view showing a referential example.

FIG. 5B is a cross sectional view showing the referential example.

FIG. 5C is a cross sectional view showing the referential example.

FIG. 6 is an enlarged view of a portion indicated by a dotted ellipse A of FIG. 1.

FIG. 7A is an enlarged view of a portion indicated by a dotted rectangle B of FIG. 6.

FIG. 7B is a view for explaining temperature distribution in the cross sectional view shown in FIG. 7A.

FIG. 8 is a cross sectional view showing an example when the lift pin moves up.

FIG. 9 is a cross sectional view showing another example when the lift pin moves up.

FIG. 10 is a cross sectional view schematically showing an example of a substrate processing apparatus in accordance with a second embodiment of the present invention.

FIG. 11 is a cross sectional view schematically showing an example of a substrate processing apparatus in accordance with a third embodiment of the present invention.

FIG. 12 is an enlarged cross sectional view showing a joint portion between a heater plate and a thermal insulator.

FIG. 13 is an enlarged cross sectional view showing the joint portion between the heater plate and the thermal insulator.

FIG. 14 is an enlarged cross sectional view showing a joint portion between a heater plate and a thermal insulator in a substrate processing apparatus in accordance with a fourth embodiment of the present invention.

### DETAILED DESCRIPTION OF THE EMBODIMENTS

Hereinafter, embodiments of the present invention will be described in detail with reference to the accompanying drawings.

### First Embodiment

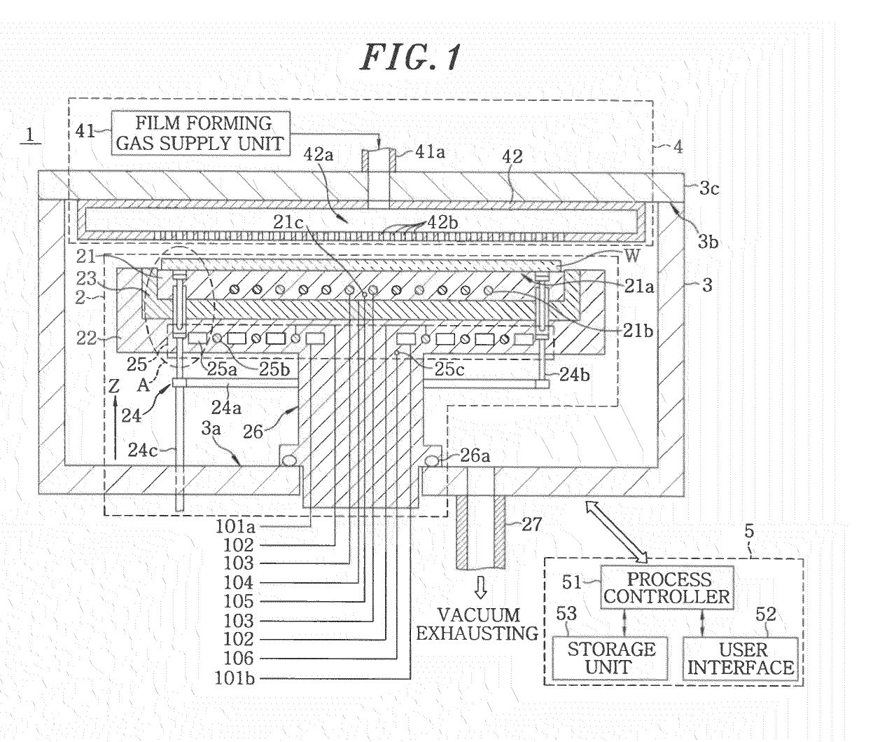

FIG. 1 is a cross sectional view schematically showing an example of a substrate processing apparatus in accordance with a first embodiment of the present invention.

As shown in FIG. 1, the substrate processing apparatus of the first embodiment is a CVD apparatus 1 for performing, e.g., a film forming process on a target substrate (in this embodiment, a semiconductor wafer) W. The CVD apparatus 1 includes a substrate mounting mechanism 2, a chamber 3 accommodating the substrate mounting mechanism 2, a film forming section 4 for performing a film forming process on a target substrate (in this embodiment, a semiconductor wafer) W, and a control section 5 for controlling the CVD apparatus 1.

The substrate mounting mechanism 2 includes a heater plate 21, a temperature control jacket 22, a thermal insulator 23 and a substrate lift mechanism 24.

The heater plate 21 has a substrate mounting surface 21a on which the target substrate is placed. A heater (hereinafter, referred to as a “heater electrode”) 21b for heating the target substrate W is embedded in the heater plate 21. The heater electrode 21b heats a temperature of the target substrate W to, e.g., a deposition temperature at which a film is deposited. The target substrate W is in contact with only the heater plate 21. In the present embodiment, the heater electrode 21b is a heating resistor enclosed in the heater plate 21. The heater plate 21 may be made of metal or ceramics. The metal may include aluminum and the ceramics may include aluminum nitride. In this embodiment, the heater plate 21 is made of aluminum.

The temperature control jacket 22 is provided to cover at least a surface of the heater plate 21 other than the substrate mounting surface 21a. A temperature control unit is embedded in the temperature control jacket 22. The temperature control unit 25 adjusts the temperature of the temperature control jacket 22 to become a non-deposition temperature below the deposition temperature in the film forming process.

The temperature control unit 25 includes a temperature control fluid circulating mechanism 25a for adjusting (increasing or decreasing) the temperature of the temperature control jacket 22 and a heater 25b for heating the temperature of the temperature control jacket 22. The temperature control fluid circulating mechanism 25a uses cooling water as a temperature control fluid. A water cooling pipe for circulating the cooling water is enclosed in the temperature control jacket 22.

The heater (heater electrode) 25b also has a heating resistor enclosed in the temperature control jacket 22. In the present embodiment, the water cooling pipe and the heating resistor are alternately arranged. Further, only one of the temperature control fluid circulating mechanism 25a and the heater 25b may be provided as the temperature control unit 25. The temperature control jacket 22 may be made of metal or ceramics. The metal may include aluminum, and the ceramics may include aluminum nitride. In this embodiment, the temperature control jacket 22 is made of aluminum.

The heater plate 21 and the temperature control jacket are fixed at an upper end of a support member 26. A lower end of the support member 26 is fixed at a bottom portion 3a of the chamber 3. Further, a seal member 26a is interposed to seal between the support member 26 and the bottom portion 3a.

A cooling water supply line 101a, a cooling water discharge line 101b, a heater electrode line 102 of the temperature control jacket 22, a heater electrode line 103 of the heater plate 21, a gas purge line 104, a thermocouple line 105 for temperature control of the heater plate 21, a thermocouple line 106 for temperature control of the temperature control jacket 22 and the like are provided to pass through the inside of the support member 26.

The cooling water supply line 101a supplies cooling water for the temperature control jacket to the temperature control fluid circulating mechanism 25a. The cooling water discharge line 101b exhausts the cooling water from the temperature control fluid circulating mechanism 25a.

The heater electrode line 102 supplies a power to the heater electrode 25b of the temperature control jacket 22. In the same way, the heater electrode line 103 supplies a power to the heater electrode 21b of the heater plate 21.

The thermocouple lines 105 and 106 are connected to thermocouples 21c and 25c provided in the heater plate 21 and the temperature control jacket 22, respectively. These thermocouples 21c and 25c are used for temperature control of the heater plate 21 and the temperature control jacket 22.

Further, the gas purge line 104 will be described in the following embodiment.

Although the support member 26 and the temperature control jacket 22 formed as a single member are illustrated in FIG. 1, the support member 26 and the temperature control jacket 22 may be formed separately.

Further, the temperature control jacket 22 itself may be formed as a single member, but may be formed as separate members. As an example of the separate members, the temperature control jacket 22 may include a part for covering a bottom portion of the heater plate 21 and a part for covering a side portion of the heater plate 21.

In the first embodiment, the thermal insulator 23 is interposed between the heater plate 21 and the temperature control jacket 22. The thermal insulator 23 suppresses heat transfer between the heater plate 21 and the temperature control jacket 22. Accordingly, the heater plate 21 is hardly influenced by the temperature of the temperature control jacket 22 and, similarly, the temperature control jacket 22 is hardly influenced by the temperature of the heater plate 21. Further, temperature control, e.g., temperature uniformity control, of the heater plate 21 and the temperature control jacket 22 can be more accurately performed.

The thermal insulator 23 may be made of a material having lower thermal conductivity than materials of which the heater plate 21 and the temperature control jacket 22 are made, e.g., metal, ceramics or quartz. The metal may include, e.g., stainless steel (SUS) and the ceramics may include, e.g., alumina. In the present embodiment, the thermal insulator 23 is made of stainless steel.

In the same manner as the temperature control jacket 22, the thermal insulator 23 may be formed as a single member or separate members. As an example of the separate members, the thermal insulator 23 may include a part for covering a bottom portion of the heater plate 21 and a part for covering a side portion of the heater plate 21 in the same way as the temperature control jacket 22.

The substrate lift mechanism 24 has a lifter arm 24a, lift pins 24b attached to the lifter arm 24a, and a shaft 24c for vertically moving the lifter arm 24a. The lift pins 24b are inserted into lift pin insertion holes formed in the temperature control jacket 22, the thermal insulator 23 and the heater plate 21. When the shaft 24c is driven in a Z direction to lift up the target substrate W, the lifter arm 24a is moved up and the lift pins 24b attached to the lifter arm 24a press the backside of the target substrate W to lift up the target substrate W from the substrate mounting surface 21a.

Reversely, when the shaft 24c is driven to lower the target substrate W, the lifter arm 24a is moved down and, accordingly, the lift pins 24b are separated from the backside of the target substrate W and the target substrate W is mounted on the substrate mounting surface 21a.

The chamber 3 accommodates the substrate mounting mechanism 2. The bottom portion 3a of the chamber 3 to which the support member 26 is fixed as described above is connected to a gas exhaust pipe 27. The gas exhaust pipe 27 is connected to a vacuum exhaust device (not shown) and, accordingly, the chamber 3 can be vacuum evacuated if necessary. An upper lid 3c is provided to an upper portion 3b of the chamber 3.

A film forming section 4 includes a film forming gas supply unit 41 and a shower head 42.

The film forming gas supply unit 41 supplies a specific film forming gas into the chamber 3 via a film forming gas supply pipe 41a. The film forming gas supply pipe 41a is connected to a diffusion space 42a of the shower head 42. The shower head 42 is attached to the upper lid 3c and a plurality of gas discharge holes 42b are formed at a surface of the shower head 42 facing the target substrate W. The film forming gas diffused in the diffusion space 42a is discharged into the chamber 3 through the gas discharge holes 42b. When the discharged film forming gas is supplied to the target substrate W having a deposition temperature, a film is formed on the surface of the target substrate W.

The control section 5 includes a process controller 51 having a micro processor (computer) and a user interface 52 having a keyboard through which an operator inputs commands to manage the CVD apparatus 1, a display for displaying an operation status of the substrate processing apparatus, or the like. The control section 5 further includes a storage unit 53 for storing therein a control program for allowing the process controller 51 to implement various processes performed in the CVD apparatus 1 and/or a program (i.e., a recipe) for executing processes in the CVD apparatus 1 in accordance with various data and process conditions.

Further, the recipe is stored in a storage medium of the storage unit 53. The storage medium may be a hard disk, or a portable storage medium, such as a CD-ROM, a DVD, or a flash memory. Further, the recipe may be appropriately transmitted from another apparatus via, e.g., a dedicated line. If necessary, a certain recipe may be retrieved from the storage unit 53 in accordance with an instruction inputted through the user interface 52 and implemented by the process controller 51 such that a desired process is performed in the CVD apparatus 1 under control of the process controller 51.

Further, in the present embodiment, the recipe includes a temperature control program for controlling the temperatures of the heater plate 21 and the temperature control jacket 22. The temperature control program is stored in the storage medium. For example, in the film forming process, the control section 5 heats the heater electrode 21b of the heater plate 21 to increase a temperature of the target substrate W to a deposition temperature at which film deposition is performed, and also controls the temperature control unit 25 such that the temperature control jacket 22 has a non-deposition temperature below the deposition temperature.

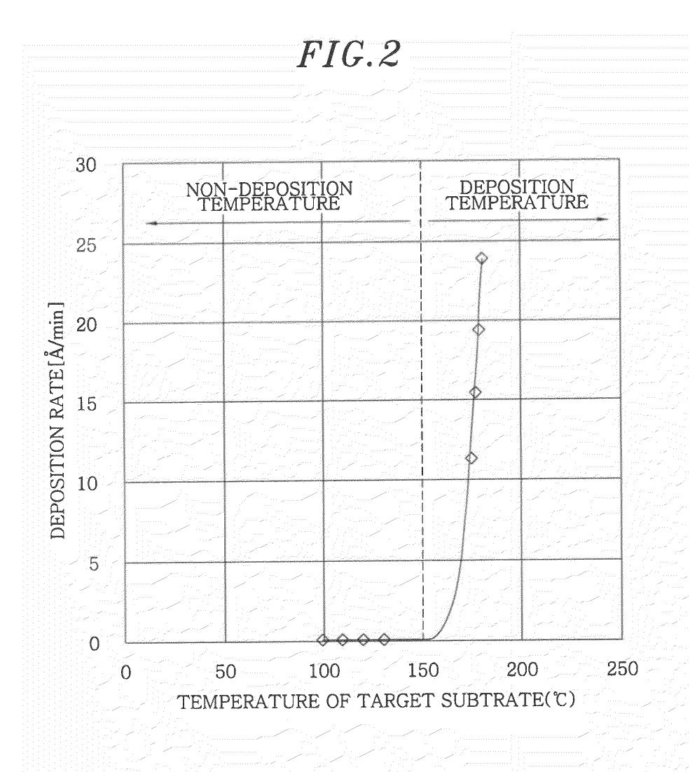

FIG. 2 illustrates a relationship between the temperature of the target substrate and the deposition rate. In an example of FIG. 2, ruthenium (Ru) is deposited by using a CVD method.

As shown in FIG. 2, ruthenium starts to be deposited when the temperature of the target substrate W reaches about 150° C. Ruthenium is rarely deposited at a temperature below 150° C., particularly, 120° C. or less. That is, a deposition temperature of ruthenium is 150° C. or more, and a non-deposition temperature of ruthenium is below 150° C. In this example, the temperature control is performed such that ruthenium is deposited on the target substrate W while preventing ruthenium from being deposited on a portion other than the target substrate W by using the relationship between the temperature and the deposition rate.

For example, in the film forming process, the heater electrode 21b of the heater plate 21 is controlled such that the target substrate W has a deposition temperature of 150° C. or more at which ruthenium is deposited, and the temperature control unit 25 is controlled such that the temperature control jacket 22 has a non-deposition temperature below 150° C.

Further, in the example of FIG. 2, Ru₃(CO)₁₂ (ruthenium complex compound) was used as a source gas of ruthenium. The film forming process is thermal decomposition of Ru₃ (CO)₁₂, wherein Ru and Co are separated by thermal decomposition and a Ru film is formed on the target substrate W.

In accordance with the CVD apparatus 1 of the first embodiment, the heater electrode 21b of the heater plate 21 is set to have a deposition temperature, and the temperature control jacket 22 that covers at least a surface of the heater plate 21 other than the substrate mounting surface 21a is set to have a non-deposition temperature. Accordingly, a film can be deposited on the target substrate W mounted on the substrate mounting surface 21a while preventing a film from being deposited on a portion other than the target substrate W. Therefore, it is possible to reduce generation of particles and to improve quality of semiconductor devices and production yield.

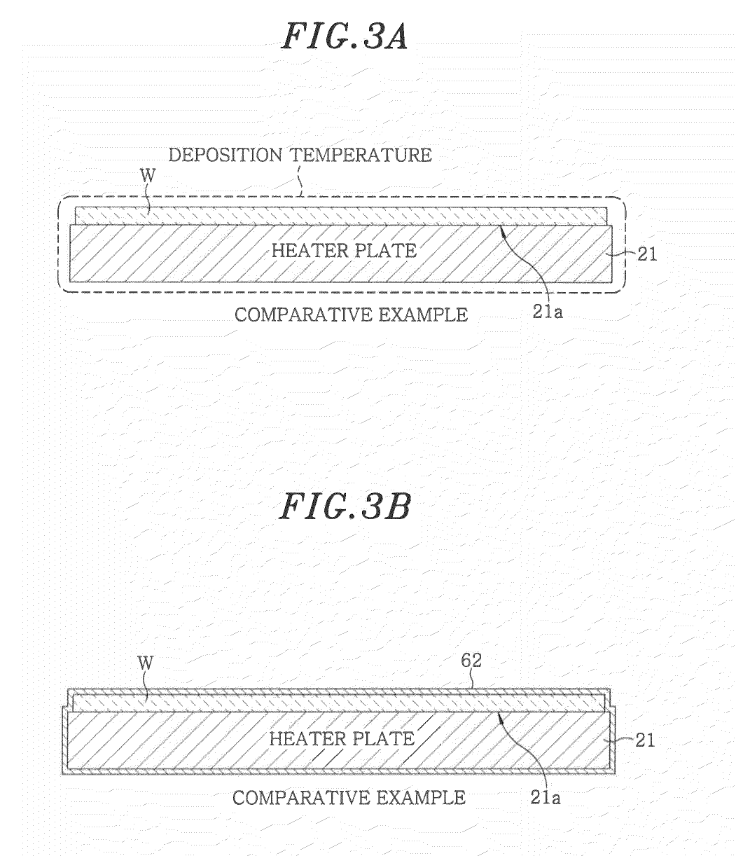

A comparative example is shown in FIGS. 3A and 3B.

As shown in FIG. 3A, when the temperature control jacket 22 is not provided, substantially the entire surface of the heater plate 21 is heated to a deposition temperature. Consequently, as shown in FIG. 3B, a film 62 is deposited on substantially the entire surface of the heater plate 21 in addition to the target substrate W.

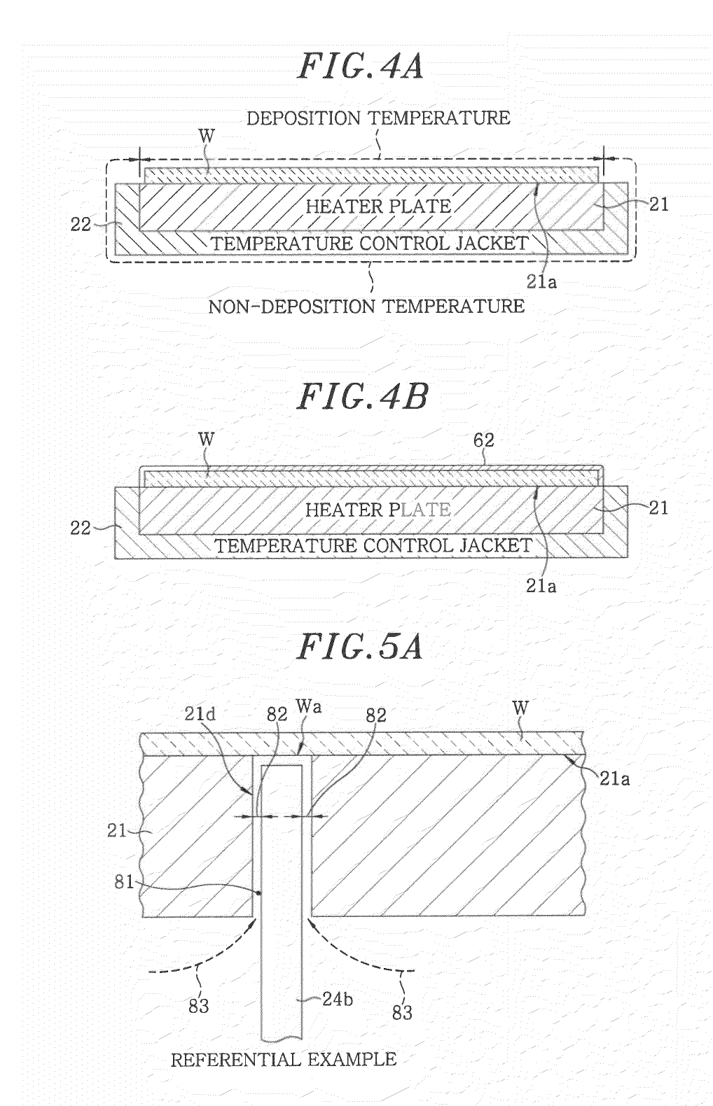

With the CVD apparatus 1 in accordance with the first embodiment, however, since the temperature control jacket 22 is provided to cover at least a surface of the heater plate 21 other than the substrate mounting surface 21a, as shown in FIG. 4A, only the substrate mounting surface 21a can be set to have a deposition temperature and a portion covered with the temperature control jacket 22 can be set to have a non-deposition temperature. As a result, as shown in FIG. 4B, the film 62 can be selectively deposited only on the target substrate W. Since the film 62 is not deposited on the temperature control jacket 22, it is possible to remove a cause of particles in the chamber 3.

Further, with the CVD apparatus 1 of the first embodiment, the film can be deposited only on the target substrate W and, thus, the number of cleaning operations performed in the chamber 3 can be reduced. For example, no cleaning operation may be performed.

By reducing the number of cleaning operations to be performed in the chamber 3, time required for operations other than film formation, e.g., cleaning and maintenance, in the CVD apparatus 1 can be decreased, thereby enhancing throughput in the manufacture of the semiconductor devices.

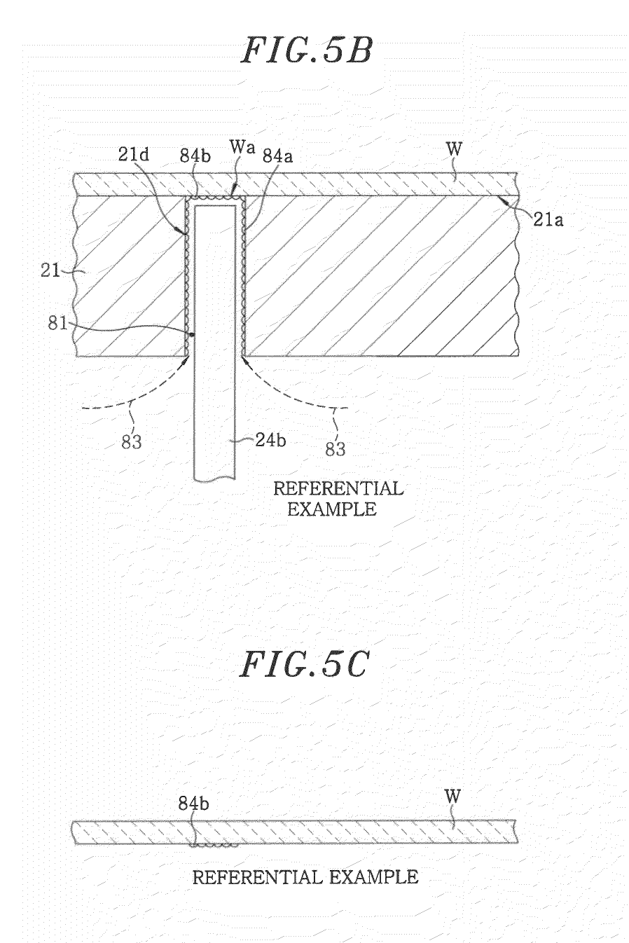

Meanwhile, as described above, the lift pins 24b are inserted into lift pin insertion holes. The lift pins 24b move vertically in the insertion holes to lift the target substrate W up and down. A gap, i.e., clearance for smooth movement is set between each of the lift pins 24b and each of the lift pin insertion holes. An example of the lift pin insertion hole with a clearance is illustrated in FIG. 5A.

As shown in FIG. 5A, the lift pin 24b is inserted in a lift pin insertion hole 81. A clearance 82 is set between the lift pin 24b and the lift pin insertion hole 81. During the film forming process, a film forming gas 83 reaches the backside of the heater plate 21 as well as the surface of the target substrate W. The film forming gas 83 that has reached the backside of the heater plate 21 may be introduced into the lift pin insertion hole 81 via the clearance 82. Since the lift pin insertion hole 81 is formed in the heater plate 21, the film forming gas 83 introduced into the lift pin insertion hole 81 is in contact with the heater plate 21 having a deposition temperature or more.

Further, an upper end portion of the lift pin 24b, i.e., a portion in contact with the target substrate W, may be separated from the target substrate W when the target substrate W is placed on the substrate mounting surface 21a of the heater plate 21. Accordingly, the film forming gas 83 is brought into contact with the backside of the target substrate W as well as the heater plate 21 in the lift pin insertion hole 81. The target substrate W has definitely a deposition temperature or more during the film forming process. Although the upper end portion of the lift pin 24b is in contact with the target substrate W, the lift pin 24b cannot completely cover the backside of the target substrate W due to the clearance 82. That is, the backside of the target substrate W comes into contact with the film forming gas 83 via the clearance 82.

As described above, the film forming gas 83 may be in contact with the backside of the target substrate W and the heater plate 21 having a deposition temperature or more in the lift pin insertion hole 81. If the film forming gas 83 comes into contact with the backside of the target substrate W and the heater plate 21 having a deposition temperature or more, as shown in FIG. 5B, films 84a and 84b are deposited on a surface 21d of the heater plate 21 that is exposed in the lift pin insertion hole 81 and a surface Wa of the target substrate W that is exposed in the lift pin insertion hole 81.

The lift pin 24b is also heated by the heat from the heater plate 21 in the lift pin insertion hole 81. Accordingly, the lift pin 24b may have a deposition temperature or more. When the lift pin 24b has a deposition temperature or more, a film is also deposited on the lift pin 24b although not shown.

The film 84a formed on the surface 21d may cause generation of particles in the chamber 3. Meanwhile, the film 84b may cause not only generation of particles in the chamber 3 but also so-called cross contamination that is contamination between chambers when the target substrate W with the film 84b is transferred to a chamber other than the chamber 3.

In order to solve the above-described problem, the following investigation on the lift pin insertion hole 81 of the CVD apparatus 1 of the first embodiment was conducted.

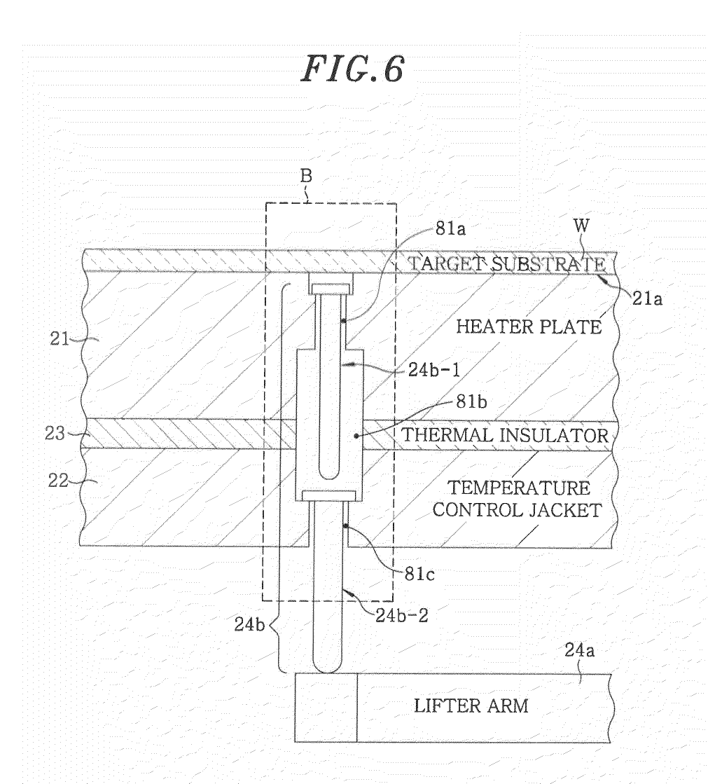

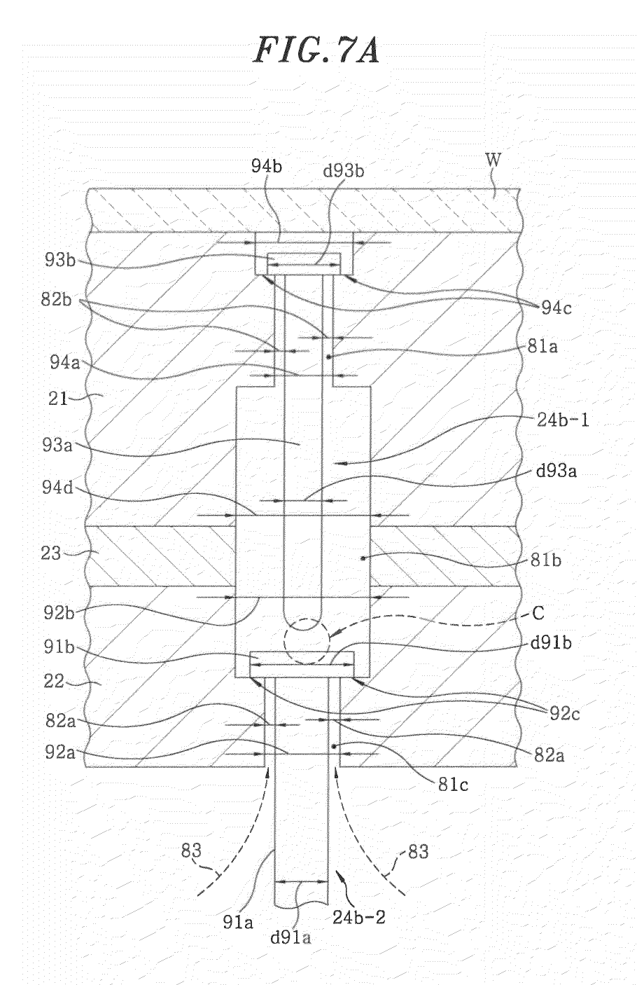

FIG. 6 is a cross sectional view showing a lift pin structure of the CVD apparatus 1 in accordance with the first embodiment of the present invention. FIG. 6 is an enlarged view of a portion indicated by a dotted ellipse A in FIG. 1. Further, FIGS. 7A and 7B are enlarged views of a portion indicated by a dotted rectangle B of FIG. 6.

As shown in FIG. 6, each of the lift pins 24b of the CVD apparatus 1 in accordance with the first embodiment is of split type. In the present embodiment, the lift pin 24b is split by two, i.e., an upper lift pin 24b-1 and a lower lift pin 24b-2. The upper lift pin 24b-1 is inserted into a lift pin insertion hole 81a formed in the heater plate 21 and a lift pin insertion hole 81b formed in the thermal insulator 23. The lower lift pin 24b-2 is inserted into a lift pin insertion hole 81c formed in the temperature control jacket 22.

As shown in FIG. 7A, the lower lift pin 24b-2 has a shaft 91a and a cover 91b. The cover 91b is provided at an upper end portion of the shaft 91a and has a diameter d91b larger than a diameter d91a of the shaft 91a. The lift pin insertion hole 81c formed in the temperature control jacket serves as a multi-stepped hole having portions with different diameters such that the lower lift pin 24b-2 having portions with different diameters passes therethrough.

In the present embodiment, the lift pin insertion hole 81c serves as a two-stepped hole, which includes a small diameter portion 92a having a diameter to pass only the shaft 91a therethrough and a large diameter portion 92b having a diameter to pass both the shaft 91a and the cover 91b therethrough. In the lift pin insertion hole 81c of a two-stepped hole, when the lower lift pin 24b-2 moves down, the cover 91b is locked at a boundary portion 92c between the small diameter portion 92a and the large diameter portion 92b. Accordingly, the cover 91b closes a clearance 82a set in the small diameter portion 92a, thereby preventing the film forming gas 83 from reaching the inside of the lift pin insertion hole 81a formed in the heater plate 21.

Further, although the film forming gas 83 is introduced into the lift pin insertion hole 81c via the clearance 82a, as shown in FIG. 7B, film deposition does not occur because the temperature control jacket 22 has a non-deposition temperature below a deposition temperature.

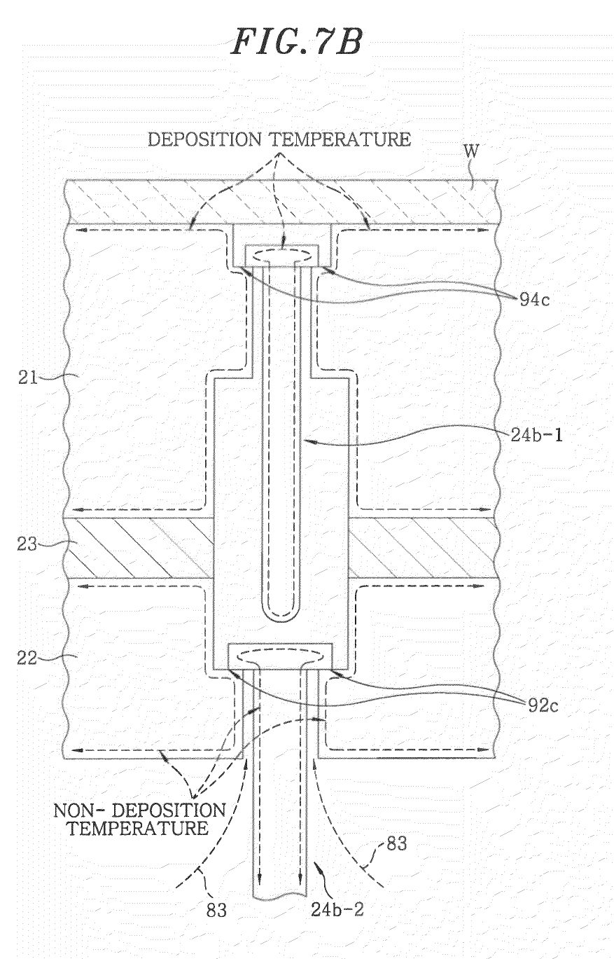

Meanwhile, the upper lift pin 24b-1 includes a shaft 93a and a cover 93b provided at an upper end portion of the shaft 93a in the same way as the lower lift pin 24b-2. The cover 93b has a diameter d93b larger than a diameter d93a of the shaft 93a. The lift pin insertion hole 81a formed in the heater plate 21 is also a two-stepped hole, which includes a small diameter portion 94a having a diameter to pass only the shaft 93a therethrough and a large diameter portion 94b having a diameter to pass both the shaft 93a and the cover 93b therethrough. FIG. 8 illustrates a cross sectional view when the lift pin 24b moves up.

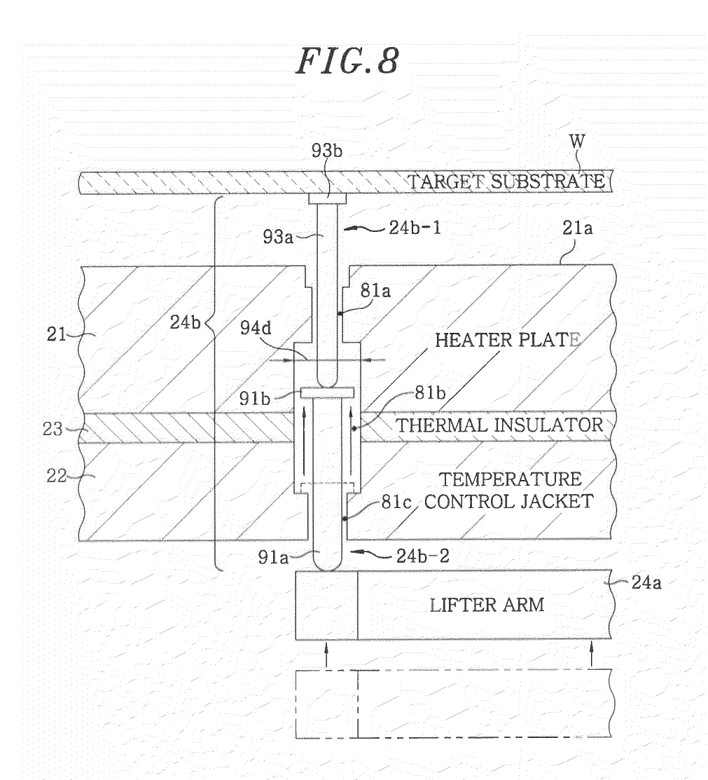

As shown in FIG. 8, the cover 91b of the lower lift pin 24b-2 passes through the lift pin insertion hole 81b formed in the thermal insulator 23 and, then, is moved up to a position in the lift pin insertion hole 81a formed in the heater plate 21. Accordingly, the lift pin insertion hole 81b has a diameter to pass the cover 91b therethrough, and a lower portion of the lift pin insertion hole 81a is formed of a large diameter portion 94d having a diameter to pass the cover 91b therethrough. However, as shown in FIG. 9, if it is intended that the cover 91b does not reach the thermal insulator 23 and the heater plate 21 when the lift pin 24b moves up, the lift pin insertion hole 81b may have a diameter to pass only the shaft 93a therethrough and, accordingly, the lift pin insertion hole 81a may have a two-stepped structure having the small diameter portion 94a and the large diameter portion 94b.

In the lift pin insertion hole 81a, as shown in FIG. 7A, the cover 93b is locked at a boundary portion 94c between the small diameter portion 94a and the large diameter portion 94b when the upper lift pin 24b-1 moves down. Accordingly, the cover 93b closes the clearance 82b set in the small diameter portion 94a, and the upper lift pin 24b-1 dose not move down. By this configuration, as illustrated by a dashed-line circle C of FIG. 7A, the lower lift pin 24b-2 is separated from the upper lift pin 24b-1 in a non-contact state in which the lift pin 24b moves down. During at least the film forming process, the lower lift pin 24b-2 and the upper lift pin 24b-1 becomes the non-contact state.

The cover 93b of the upper lift pin 24b-1 comes into contact with the heater plate 21 at the boundary portion 94c. Since the upper lift pin 24b-1 is in contact with the heater plate 21, the temperature of the upper lift pin 24b-1 easily increases. As shown in FIG. 7B, the temperature of the upper lift pin 24b-1 may increase above a deposition temperature. If the upper lift pin 24b-1 having a temperature above a deposition temperature is in contact with the lower lift pin 24b-2, a heat is transferred from the upper lift pin 24b-1 to the lower lift pin 24b-2 and, accordingly, the temperature of the lower lift pin 24b-2 may be increased above a deposition temperature. The lower lift pin 24b-2 is in contact with the film forming gas via the clearance 82a set in the small diameter portion 92a. If the temperature of the lower lift pin 24b-2 increases above a deposition temperature, a film is deposited on the lower lift pin 24b-2.

Such problem of the film deposition can be solved by causing the upper lift pin 24b-1 not to make contact with the lower lift pin 24b-2 at least during the film forming process and preventing heat transfer from the upper lift pin 24b-1 to the lower lift pin 24b-2.

Further, the cover 91b of the lower lift pin 24b-2 comes into contact with the temperature control jacket 22 at the boundary portion 92c. Accordingly, as shown in FIG. 7B, heat can be easily transferred from the temperature control jacket 22 to the lower lift pin 24b-2. By this configuration in which heat transfer from the temperature control jacket 22 to the lower lift pin 24b-2 easily occurs, the temperature of the lower lift pin 24b-2 can be more easily set to a non-deposition temperature as compared to a case in which the lower lift pin 24b-2 is not in contact with the temperature control jacket 22. When the temperature of the lower lift pin 24b-2 is a non-deposition temperature, although the film forming gas is in contact with the lower lift pin 24b-2, film deposition does not occur.

With the CVD apparatus 1 in accordance with the first embodiment, the heater electrode 21b of the heater plate 21 is set to have a deposition temperature while the temperature control jacket 22 that covers at least a surface of the heater plate 21 other than the substrate mounting surface 21a is set to have a non-deposition temperature. Accordingly, it is possible to prevent a film from being deposited on a portion other than the target substrate W. Accordingly, it is possible to reduce generation of particles and to improve quality of semiconductor devices and production yield.

As described above, in the first embodiment, the lift pin 24b is configured to have a split structure, and the lower lift pin 24b-2 has the shaft 91a and the cover 91b having a diameter larger than that of the shaft 91a, which is provided at the upper end portion and locked in the lift pin insertion hole 81c formed in the temperature control jacket 22. Accordingly, when the lift pin 24b-2 is lowered down, the cover 91b closes the clearance 82a, thereby preventing the film forming gas from reaching the insertion hole 81a formed in the heater plate 21 or the like via the clearance 82a. Thus, it is possible to suppress film deposition on the backside of the target substrate or the inner wall of the lift pin insertion hole 81a.

Further, in the first embodiment, the upper lift pin 24b-1 has also a cover by which the upper lift pin 24b-1 is locked in the lift pin insertion hole 81a formed in the heater plate 21. The locked upper lift pin 24b-1 does not further move down. By this configuration, the lower lift pin 24b-2 is separated from the upper lift pin 24b-1 at least during the film forming process, thereby suppressing an increase in the temperature of the lower lift pin 24b-2. As a result, it is possible to prevent film deposition on the lower lift pin 24b-2.

In accordance with the first embodiment of the present invention, even though the substrate mounting mechanism has the lift pin insertion holes, it is possible to reduce generation of particles and to improve quality of semiconductor devices and production yield.

### Second Embodiment

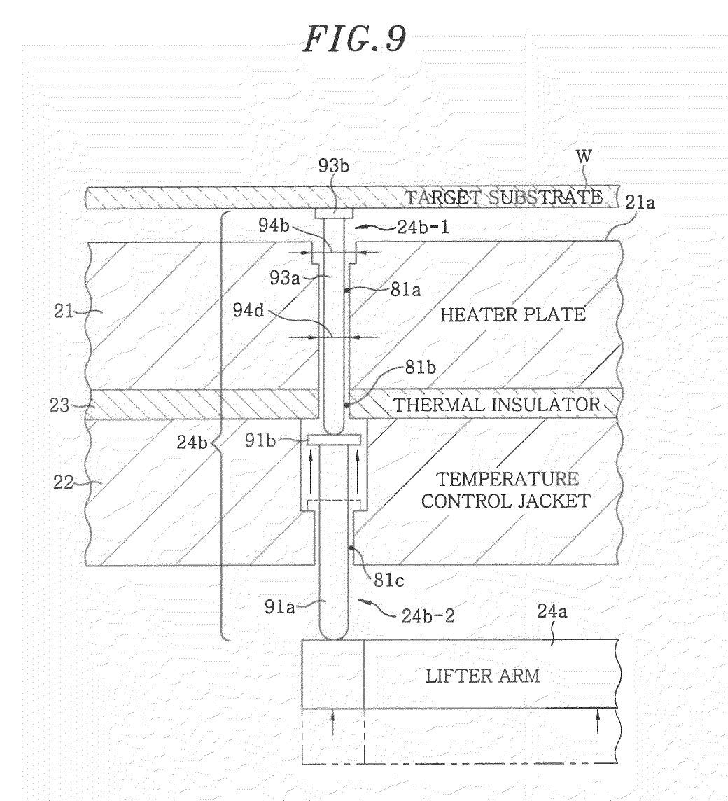

FIG. 10 is a cross sectional view schematically showing an example of a substrate processing apparatus in accordance with a second embodiment of the present invention. In FIG. 10, the same reference numerals are given to the same components as those in FIG. 1, and only different features will be described.

As shown in FIG. 10, a CVD apparatus 1a of the second embodiment is different from the CVD apparatus 1 of the first embodiment in that the temperature control unit 25 is omitted from the temperature control jacket 22.

The thermal insulator 23 is interposed between the heater plate 21 and the temperature control jacket 22. The thermal insulator 23 suppresses heat transfer from the heater plate 21 to the temperature control jacket 22. Accordingly, even though the temperature control jacket 22 itself does not perform temperature control, the temperature of the temperature control jacket 22 can be set to have a non-deposition temperature lower than the temperature of the heater plate 21, i.e., a deposition temperature. In this case, the temperature control unit 25 can be omitted.

In the second embodiment, the temperature control jacket 22 can have a non-deposition temperature without the temperature control unit 25, thereby preventing film deposition on the temperature control jacket 22. Thus, the same effect as that of the first embodiment can be obtained.

As in the second embodiment, the temperature control jacket 22 can be set to have a non-deposition temperature by using only the thermal insulator 23 without the temperature control unit 25.

### Third Embodiment

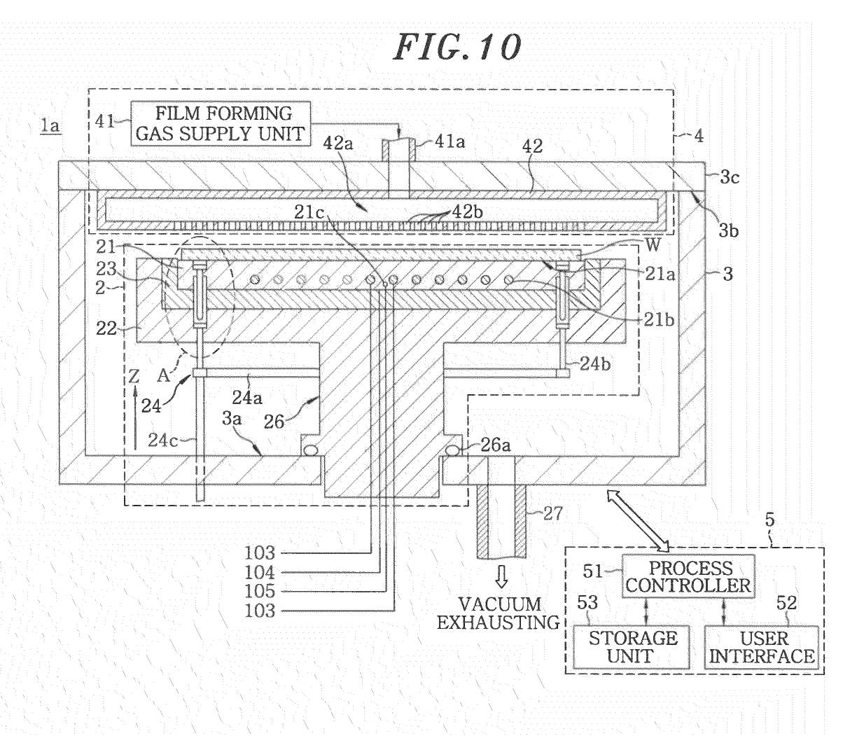

FIG. 11 is a cross sectional view schematically showing an example of a substrate processing apparatus in accordance with a third embodiment of the present invention. In FIG. 11, the same reference numerals are given to the same components as those in FIG. 1, and only different features will be described.

As shown in FIG. 11, a CVD apparatus 1b of the third embodiment is different from the CVD apparatus 1 of the first embodiment in that the thermal insulator 23 is omitted between the heater plate 21 and the temperature control jacket 22.

The temperature control jacket 22 of the CVD apparatus 1b has the temperature control unit 25 as in the first embodiment. In this case, the temperature of the temperature control jacket 22 can be adjusted to a non-deposition temperature without the thermal insulator 23. Accordingly, the thermal insulator 23 may be omitted if the temperature control jacket 22 has the temperature control unit 25.

In the third embodiment, the temperature control jacket 22 can be set to have a non-deposition temperature without the thermal insulator 23, thereby preventing film deposition on the temperature control jacket 22. Thus, the same effect as that of the first embodiment can be obtained.

As in the third embodiment, the temperature control jacket 22 can be set to have a non-deposition temperature by using only the temperature control unit 25 without the thermal insulator 23.

Alternatively, the temperature control jacket 22 itself may be formed of a thermal insulator. Also in this case, the thermal insulator 23 may be omitted.

Further, when the temperature control jacket 22 itself is formed of a thermal insulator, the temperature control jacket 22 itself can suppress heat transfer from the heater plate 21. Accordingly, the temperature control unit 25 may be omitted as in the second embodiment.

### Fourth Embodiment

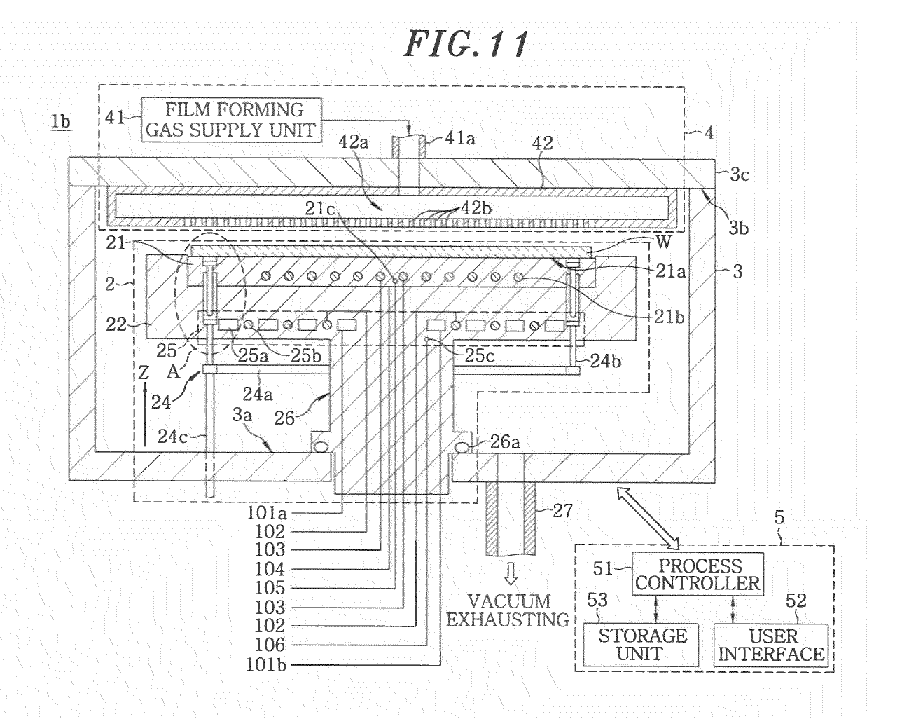

FIGS. 12 to 14 are enlarged cross sectional views showing a joint portion between the heater plate 21 and the thermal insulator 23.

Although the heater plate 21 and the thermal insulator 23 are jointed to each other, microscopically, a very small gap 60 is formed between the heater plate 21 and the thermal insulator 23 as shown in FIG. 12. During the film forming process, the film forming gas 61 is introduced into the gap 60 as indicated by an arrow A.

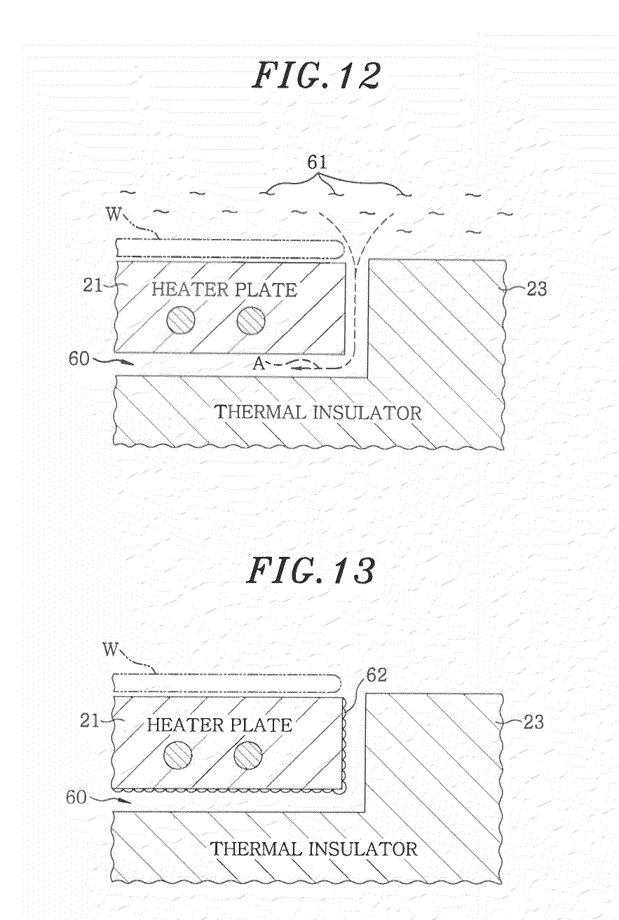

Since the heater plate 21 reaches the deposition temperature, when the film forming gas is in contact with the heater plate 21, the film is deposited on the heater plate 21. FIG. 13 illustrates a state in which the film 62 is deposited on the heater plate 21 by the film forming gas 61 introduced into the gap 60. The film 62 deposited on a portion of the heater plate 21 facing the gap 60 may cause generation of particles.

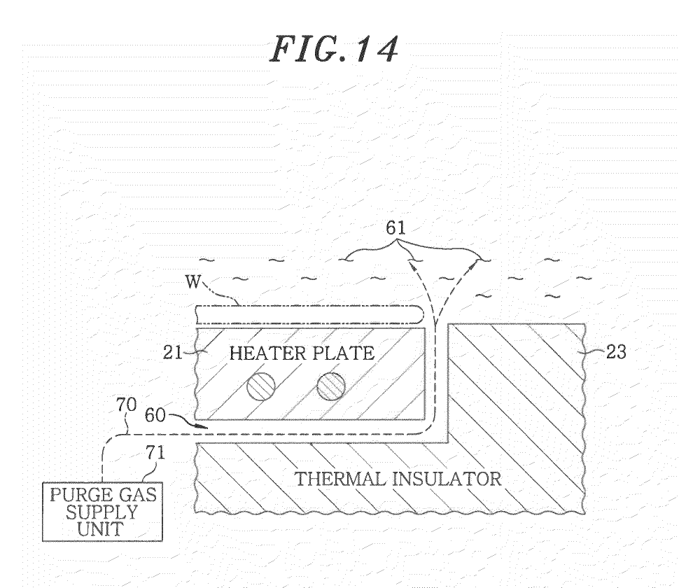

Accordingly, in the fourth embodiment, as shown in FIG. 14, a purge gas supply unit 71 supplies a purge gas 70 to the gap 60 between the heater plate 21 and the thermal insulator 23 such that the purge gas 70 passes through the gap 60 and is discharged therefrom. Further, a supply path of the purge gas 70 is represented as the “gas purge line 104” in FIGS. 1, 10 and 11.

The film forming gas 61 is difficult to enter the gap 60 by flowing the purge gas 70 in the gap 60. As a result, it is possible to prevent the film 62 from being deposited on the portion of the heater plate 21 facing the gap 60.

Further, although the purge gas 70 flows in the gap 60 between the heater plate 21 and the thermal insulator 23 in an example of FIG. 14, when the thermal insulator 23 is not provided, for example, as in the third embodiment, the purge gas 70 may pass through a gap between the heater plate 21 and the temperature control jacket 22 and be discharged from the gap.

Further, the purge gas 70 may be supplied if necessary.

While the invention has been shown and described with respect to the embodiments, various changes and modification may be made without being limited thereto.

For example, although the CVD apparatus was used in the above embodiments, the present invention may be also applied to any apparatus for film deposition, e.g., a plasma CVD apparatus and an ALD apparatus, without being limited thereto.

Further, although ruthenium was used for a deposited film in the above embodiments, it is not limited thereto.

What is claimed is:

1. A substrate mounting mechanism comprising:
a heater plate which includes a substrate mounting surface on which a target substrate is placed, a heater embedded therein to heat the target substrate to a deposition temperature at which a film is deposited, and a first lift pin insertion hole having a large diameter portion at a side close to the substrate mounting surface and a small diameter portion with a diameter smaller than that of the large diameter portion at a side away from the substrate mounting surface;
a temperature control jacket which is formed to cover at least a surface of the heater plate other than the substrate mounting surface, is set to have a non-deposition temperature below the deposition temperature, and includes a second lift pin insertion hole having a large diameter portion at a side close to the substrate mounting surface and a small diameter portion with a diameter smaller than that of the large diameter portion at a side away from the substrate mounting surface;
a first lift pin which is inserted into the first lift pin insertion hole and includes a cover inserted into the large diameter portion of the first lift pin insertion hole and a shaft connected to the cover and inserted into both the large diameter portion and the small diameter portion of the first lift pin insertion hole; and
a second lift pin which is inserted into the second lift pin insertion hole and includes a cover inserted into the large diameter portion of the second lift pin insertion hole and a shaft connected to the cover and inserted into both the large diameter portion and the small diameter portion of the second lift pin insertion hole.

2. The substrate mounting mechanism of claim 1, wherein the first and the second lift pin are in a non-contact state during at least a film forming process.

3. The substrate mounting mechanism of claim 1, wherein the second lift pin is in contact with the temperature control jacket at least during a film forming process.

4. The substrate mounting mechanism of claim 1, wherein the temperature control jacket includes a temperature control unit.

5. The substrate mounting mechanism of claim 4, wherein the temperature control unit has a cooling medium circulating mechanism for circulating a cooling medium to adjust a temperature of the temperature control jacket.

6. The substrate mounting mechanism of claim 5, wherein the temperature control unit has a heater for adjusting a temperature of the temperature control jacket.

7. The substrate mounting mechanism of claim 1, wherein the temperature control jacket is formed by using a thermal insulator.

8. The substrate mounting mechanism of claim 1, further comprising a purge gas supply unit for supplying a purge gas between the heater plate and the temperature control jacket.

9. The substrate mounting mechanism of claim 1, further comprising a thermal insulator provided between the heater plate and the temperature control jacket.

10. The substrate mounting mechanism of claim 9, further comprising a purge gas supply unit for supplying a purge gas between the heater plate and the thermal insulator.

11. A substrate processing apparatus comprising:
a chamber accommodating a substrate mounting mechanism;
a film forming section for performing a film forming process on a target substrate; and
a substrate mounting mechanism,
wherein the substrate mounting mechanism includes:
a heater plate which includes a substrate mounting surface on which the target substrate is placed, a heater embedded therein to heat the target substrate to a deposition temperature at which a film is deposited, and a first lift pin insertion hole having a large diameter portion at a side close to the substrate mounting surface and a small diameter portion with a diameter smaller than that of the large diameter portion at a side away from the substrate mounting surface;
a temperature control jacket which is formed to cover at least a surface of the heater plate other than the substrate mounting surface, is set to have a non-deposition temperature below the deposition temperature, and includes a second lift pin insertion hole having a large diameter portion at a side close to the substrate mounting surface and a small diameter portion with a diameter smaller than that of the large diameter portion at a side away from the substrate mounting surface;
a first lift pin which is inserted into the first lift pin insertion hole and includes a cover inserted into the large diameter portion of the first lift pin insertion hole and a shaft connected to the cover and inserted into both the large diameter portion and the small diameter portion of the first lift pin insertion hole; and
a second lift pin which is inserted into the second lift pin insertion hole and includes a cover inserted into the large diameter portion of the second lift pin insertion hole and a shaft connected to the cover and inserted into both the large diameter portion and the small diameter portion of the second lift pin insertion hole.

12. The substrate processing apparatus of claim 11, wherein the first lift pin and the second lift pin are in a non-contact state at least during a film forming process.

13. The substrate processing apparatus of claim 11, wherein the second lift pin is in contact with the temperature control jacket at least during a film forming process.

14. The substrate processing apparatus of claim 11, wherein the temperature control jacket includes a temperature control unit.

15. The substrate processing apparatus of claim 14, wherein the temperature control unit has a cooling medium circulating mechanism for circulating a cooling medium to adjust a temperature of the temperature control jacket.

16. The substrate processing apparatus of claim 15, wherein the temperature control unit has a heater for adjusting a temperature of the temperature control jacket.

17. The substrate processing apparatus of claim 11, wherein the temperature control jacket is formed by using a thermal insulator.

18. The substrate processing apparatus of claim 11, further comprising a purge gas supply unit for supplying a purge gas between the heater plate and the temperature control jacket.

19. The substrate processing apparatus of claim 11, further comprising a thermal insulator provided between the heater plate and the temperature control jacket.

20. The substrate processing apparatus of claim 19, further comprising a purge gas supply unit for supplying a purge gas between the heater plate and the thermal insulator.
